(19) United States
(12) Patent Application Publication
(10) Pub. No.: US 2024/0344194 A1
(43) Pub. Date: Oct. 17, 2024

(54) METHOD OF MANUFACTURING SEMICONDUCTOR DEVICE, SUBSTRATE PROCESSING APPARATUS, AND RECORDING MEDIUM

(71) Applicant: Kokusai Electric Corporation, Tokyo (JP)

(72) Inventors: Atsuhiko ASHITANI, Toyama-shi (JP); Arito Ogawa, Toyama-shi (JP); Kota Kowa, Toyama-shi (JP)

(73) Assignee: Kokusai Electric Corporation, Tokyo (JP)

(21) Appl. No.: 18/732,442

(22) Filed: Jun. 3, 2024

Related U.S. Application Data
(63) Continuation of application No. 17/458,139, filed on Aug. 26, 2021, now abandoned.
Application No. 17/458,139 is a continuation of application No. PCT/JP2020/006791, filed on Feb. 20, 2020.

(30) Foreign Application Priority Data
Feb. 28, 2019 (JP) 2019-036184

(51) Int. Cl. C23C 16/30; C23C 16/44; C23C 16/455; C23C 16/52; H01L 21/285; H01L 21/768

(52) U.S. Cl. CPC C23C 16/303; C23C 16/4412; C23C 16/455; C23C 16/52; H01L 21/28506; H01L 21/76841

(57) ABSTRACT

There is provided a technique capable of forming a low resistance film. The technique includes sequentially repeating: a first step including a first process of supplying a reducing gas containing silicon and hydrogen and not containing halogen, in parallel with supply of a metal-containing gas, to a substrate in a process chamber; a second step including: a second process of stopping the supply of the metal-containing gas, and maintaining the supply of the reducing gas; and a third process of supplying an inert gas into the process chamber with the supply of the reducing gas stopped, and maintaining a pressure in the third process equal to a pressure in the second process or adjusting the pressure in the third process to a pressure different from the pressure in the second process; and a third step of supplying a nitrogen-containing gas to the substrate.

### CROSS-REFERENCE TO RELATED APPLICATION(S)

This application is a Continuation application of U.S. application Ser. No. 17/458,139, filed Aug. 26, 2021, which is a Bypass Continuation Application of PCT International Application No. PCT/JP2020/006791, filed Feb. 20, 2020 and designating the United States, the International Application being based upon and claiming the benefit of priority from Japanese Patent Application No. 2019-036184, filed on Feb. 28, 2019, the entire content of which is incorporated herein by reference.

### TECHNICAL FIELD

The present disclosure relates to a method of manufacturing a semiconductor device, a substrate processing apparatus, and a recording medium.

### BACKGROUND

For example, a tungsten (W) film is used for a control gate of a NAND flash memory having a three-dimensional structure, and a tungsten hexafluoride (WF₆) gas containing W is used for forming the W film. Further, a titanium nitride (TiN) film as a barrier film may be provided between the W film and an insulating film. The TiN film plays a role of enhancing the adhesion between the W film and the insulating film and also plays a role of preventing the fluorine (F) contained in the W film from diffusing into the insulating film. The film formation is generally carried out by using a titanium tetrachloride (TiCl₄) gas and an ammonia (NH₃) gas.

### SUMMARY

The present disclosure provides some embodiments of a technique capable of forming a low resistance film.

According to one or more embodiments of the present disclosure, there is provided a technique that includes sequentially repeating: a first step including a first process of supplying a reducing gas containing silicon and hydrogen and not containing halogen, in parallel with supply of a metal-containing gas, to a substrate in a process chamber; a second step including: a second process of stopping the supply of the metal-containing gas, and maintaining the supply of the reducing gas; and a third process of supplying an inert gas into the process chamber with the supply of the reducing gas stopped, and maintaining a pressure in the third process equal to a pressure in the second process or adjusting the pressure in the third process to a pressure different from the pressure in the second process; and a third step of supplying a nitrogen-containing gas to the substrate.

### BRIEF DESCRIPTION OF DRAWINGS

FIG. 1 is a vertical sectional view showing an outline of a vertical process furnace of a substrate processing apparatus.

FIG. 2 is a schematic sectional view taken along line A-A in FIG. 1.

FIG. 3 is a schematic configuration diagram of a controller of the substrate processing apparatus, and is a block diagram showing a control system of the controller.

FIG. 4 is a diagram showing a substrate processing flow in the present disclosure.

FIG. 5 is a diagram showing a gas supply sequence.

FIG. 6 is a diagram showing a gas supply sequence.

FIG. 7 is a diagram showing a gas supply sequence.

FIG. 8 is a diagram showing an inert gas flow rate ratio in a second step.

FIG. 9 is a diagram showing a gas supply sequence.

FIG. 10 is a diagram showing a gas supply sequence.

FIG. 11 is a diagram showing a gas supply sequence.

FIG. 12 is a diagram showing a gas supply sequence.

FIG. 13 is a diagram showing an example of experimental results.

### DETAILED DESCRIPTION

### One or More Embodiments

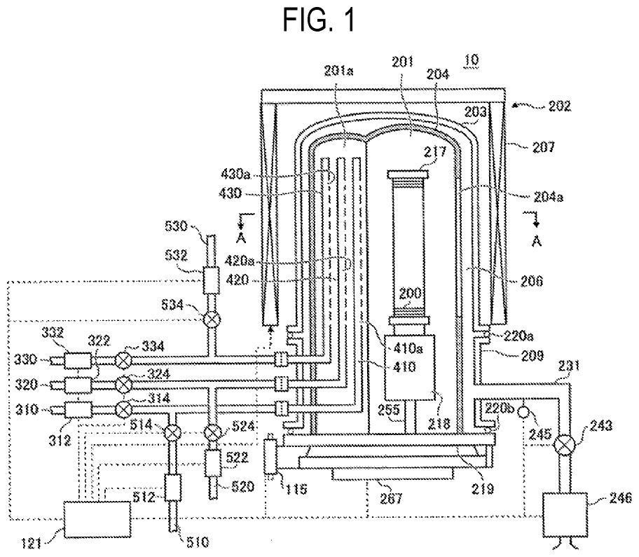

Hereinafter, one or more embodiments will be described with reference to FIGS. 1 to 4.

### (1) Configuration of Substrate Processing Apparatus

The substrate processing apparatus 10 includes a process furnace 202 in which a heater 207 as a heating means (heating mechanism or heating system) is installed. The heater 207 has a cylindrical shape, and is vertically installed by being supported on a heater base (not shown) as a holding plate.

Inside the heater 207, there is installed an outer tube 203 which constitutes a reaction container (process container) concentrically with the heater 207. The outer tube 203 is made of a heat-resistant material such as quartz (SiO₂) or silicon carbide (SiC). The outer tube 203 is formed in a cylindrical shape having a closed upper end and an open lower end. Below the outer tube 203, there is installed a manifold (inlet flange) 209 concentrically with the outer tube 203. The manifold 209 is made of, for example, a metallic material such as stainless steel (SUS). The manifold 209 is formed in a cylindrical shape having open upper and lower ends. An O-ring 220a as a seal member is installed between the upper end of the manifold 209 and the outer tube 203. As the manifold 209 is supported by the heater base, the outer tube 203 comes into a vertically installed state.

Inside the outer tube 203, there is installed an inner tube 204 that constitutes a reaction container. The inner tube 204 is made of a heat-resistant material such as quartz (SiO₂) or silicon carbide (SiC). The inner tube 204 is formed in a cylindrical shape having a closed upper end and an open lower end. A process container (reaction container) mainly includes the outer tube 203, the inner tube 204, and the manifold 209. A process chamber 201 is formed in a hollow portion of the process container (inside the inner tube 204).

The process chamber 201 is configured to be able to accommodate wafers 200 as substrates, in such a state that the wafers 200 are arranged in a horizontal posture and in multiple stages along a vertical direction by a boat 217 described later.

In the process chamber 201, nozzles 410, 420, and 430 are installed so as to penetrate the side wall of the manifold 209 and the inner tube 204. Gas supply pipes 310, 320, and 330 are connected to the nozzles 410, 420, and 430, respectively. However, the process furnace 202 of the present embodiments is not limited to the above-described form.

Mass flow controllers (MFCs) 312, 322, and 332, which are flow rate controllers (flow rate control units), and valves 314, 324, and 334, which are opening/closing valves, are respectively installed on the gas supply pipes 310, 320, and 330 sequentially from the upstream side. Gas supply pipes 510, 520, and 530 for supplying an inert gas are connected to the gas supply pipes 310, 320, and 330 on the downstream side of the valves 314, 324, and 334, respectively. MFCs 512, 522, and 532, which are flow rate controllers (flow rate control units), and valves 514, 524, and 534, which are opening/closing valves, are respectively installed on the gas supply pipes 510, 520, and 530 sequentially from the upstream side.

Nozzles 410, 420, and 430 are connected to the distal ends of the gas supply pipes 310, 320, and 330, respectively. The nozzles 410, 420, and 430 are configured as L-shaped nozzles. The horizontal portions of the nozzles 410, 420, and 430 are installed to penetrate the side wall of the manifold 209 and the inner tube 204. The vertical portions of the nozzles 410, 420, and 430 are installed inside a channel-shaped (groove-shaped) auxiliary chamber 201a that protrudes radially outward of the inner tube 204 and extends in the vertical direction. In the auxiliary chamber 201a, the vertical portions of the nozzles 410, 420 and 430 are installed to extend upward (upward in the arrangement direction of the wafers 200) along the inner wall of the inner tube 204.

The nozzles 410, 420, and 430 are installed so as to extend from a lower region of the process chamber 201 to an upper region of the process chamber 201. The nozzles 410, 420, and 430 have a plurality of gas supply holes 410a, 420a, and 430a, respectively, which are formed at positions facing the wafers 200. Thus, process gases are supplied to the wafers 200 from the gas supply holes 410a, 420a, and 430a of the nozzles 410, 420, and 430, respectively. The gas supply holes 410a, 420a, and 430a are formed over a region from the lower portion to the upper portion of the inner tube 204. The gas supply holes 410a, 420a, and 430a have the same opening area, and are installed at the same opening pitch. However, the gas supply holes 410a, 420a, and 430a are not limited to the above-described form. For example, the opening area may be gradually increased from the lower portion to the upper portion of the inner tube 204. By doing so, the flow rates of the gases supplied from the gas supply holes 410a, 420a, and 430a can be made more uniform.

The gas supply holes 410a, 420a, and 430a of the nozzles 410, 420, and 430 are installed at height positions from the bottom to the top of the boat 217, which will be described later. Therefore, the process gases supplied into the process chamber 201 from the gas supply holes 410a, 420a, and 430a of the nozzles 410, 420, and 430 are supplied to the entire arrangement region of the wafers 200 accommodated from the lower portion to the upper portion of the boat 217. The nozzles 410, 420, and 430 may be installed so as to extend from the lower region to the upper region of the process chamber 201, but are preferably installed so as to extend to the vicinity of the ceiling of the boat 217.

From the gas supply pipe 310, a precursor gas containing a metal element (metal-containing gas) as a process gas is supplied into the process chamber 201 via the MFC 312, the valve 314, and the nozzle 410. As the precursor, for example, titanium tetrachloride (TiCl₄) containing titanium (Ti) as a metal element and functioning as a halogen-based precursor (halide or halogen-based titanium precursor) is used.

From the gas supply pipe 320, a reducing gas as a process gas is supplied into the process chamber 201 via the MFC 322, the valve 324, and the nozzle 420. As the reducing gas, for example, a silane (SiH₄) gas containing silicon (Si) and hydrogen (H) and not containing halogen may be used. SiH₄ acts as a reducing agent.

From the gas supply pipe 330, a reaction gas as a process gas is supplied into the process chamber 201 via the MFC 332, the valve 334, and the nozzle 430. As the reaction gas, for example, an ammonia (NH₃) gas may be used as a N-containing gas containing nitrogen (N).

From the gas supply pipes 510, 520, and 530, for example, a nitrogen (N₂) gas as an inert gas is supplied into the process chamber 201 via the MFCs 512, 522, and 532, the valves 514, 524, and 534, and the nozzles 410, 420, and 430, respectively. Hereinafter, an example in which a N₂ gas is used as the inert gas will be described. As the inert gas, for example, a rare gas such as an argon (Ar) gas, a helium (He) gas, a neon (Ne) gas, a xenon (Xe) gas, or the like may be used in addition to the N₂ gas.

A process gas supply part (supplier) mainly includes the gas supply pipes 310, 320, and 330, the MFCs 312, 322, and 332, the valves 314, 324, and 334, and the nozzles 410, 420, and 430. However, only the nozzles 410, 420, and 430 may be considered as the process gas supply part. The process gas supply part may be simply referred to as a gas supply part. When the precursor gas is allowed to flow from the gas supply pipe 310, a precursor gas supply part (supplier) mainly includes the gas supply pipe 310, the MFC 312, and the valve 314. The nozzle 410 may be included in the precursor gas supply part. Further, when the reducing gas is allowed to flow from the gas supply pipe 320, a reducing gas supply part (supplier) mainly includes the gas supply pipe 320, the MFC 322, and the valve 324. The nozzle 420 may be included in the reducing gas supply part. Moreover, when the reaction gas is allowed to flow from the gas supply pipe 330, a reaction gas supply part (supplier) mainly includes the gas supply pipe 330, the MFC 332, and the valve 334. The nozzle 430 may be included in the reaction gas supply part. When a nitrogen-containing gas is supplied as the reaction gas from the gas supply pipe 330, the reaction gas supply part can also be referred to as nitrogen-containing gas supply part. In addition, the inert gas supply part mainly includes the gas supply pipes 510, 520, and 530, the MFCs 512, 522, and 532, and the valves 514, 524, and 534.

In the gas supply method according to the present embodiments, the gases are transported via the nozzles 410, 420, and 430 arranged in the auxiliary chamber 201a in an annular vertically-elongated space defined by the inner wall of the inner tube 204 and the end portions of the plurality of wafers 200. The gases are injected into the inner tube 204 from the gas supply holes 410a, 420a, and 430a formed in the nozzles 410, 420, and 430 at the positions facing the wafers. More specifically, the precursor gas and the like are injected in a direction parallel to the surfaces of the wafers 200 from the gas supply holes 410a of the nozzle 410, the gas supply holes 420a of the nozzle 420, and the gas supply holes 430a of the nozzle 430.

The exhaust hole (exhaust port) 204a is a through-hole formed on the side wall of the inner tube 204 at a position facing the nozzles 410, 420, and 430. The exhaust hole is, for example, a slit-shaped through-hole elongated in the vertical direction. The gas supplied from the gas supply holes 410a, 420a, and 430a of the nozzles 410, 420, and 430 into the process chamber 201 and flowing on the surfaces of the wafers 200 flows into an exhaust path 206 defined by a gap formed between the inner tube 204 and the outer tube 203 via the exhaust hole 204a. Then, the gas flowing into the exhaust path 206 flows into an exhaust pipe 231 and is discharged out of the process furnace 202.

The exhaust hole 204a is formed at a position facing the side surfaces of the plurality of wafers 200. The gas supplied from the gas supply holes 410a, 420a, and 430a to the vicinity of the wafers 200 in the process chamber 201 flows in the horizontal direction, and then flows into the exhaust path 206 through the exhaust hole 204a. The exhaust hole 204a is not limited to being configured as a slit-shaped through-hole, and may be configured by a plurality of holes.

At the manifold 209, there is installed an exhaust pipe 231 for exhausting the atmosphere in the process chamber 201. A pressure sensor 245 as a pressure detector (pressure detection part) for detecting the pressure in the process chamber 201, an APC (Auto Pressure Controller) valve 243 as an exhaust valve and a vacuum pump 246 as a vacuum exhaust device are connected to the exhaust pipe 231 sequentially from the upstream side. By opening and closing the APC valve 243 while operating the vacuum pump 246, it is possible to perform evacuation of the inside of the process chamber 201 and to stop the evacuation of the inside of the process chamber 201. Furthermore, by adjusting the opening degree of the APC valve 243 while operating the vacuum pump 246, i.e., by adjusting the exhaust conductance, it is possible to adjust the pressure in the process chamber 201. An exhaust part mainly includes the exhaust hole 204a, the exhaust path 206, the exhaust pipe 231, the APC valve 243, and the pressure sensor 245. At least the exhaust port 204a may be considered as the exhaust part. The vacuum pump 246 may be included in the exhaust part.

Below the manifold 209, there is installed a seal cap 219 as a furnace port lid capable of hermetically closing the lower end opening of the manifold 209. The seal cap 219 is configured to make contact with the lower end of the manifold 209 from below in the vertical direction. The seal cap 219 is made of, for example, a metallic material such as SUS or the like. The seal cap 219 is formed in a disk shape. On the upper surface of the seal cap 219, there is installed an O-ring 220b as a seal member that makes contact with the lower end of the manifold 209. On the opposite side of the seal cap 219 from the process chamber 201, there is installed a rotation mechanism 267 for rotating a boat 217 that accommodates the wafers 200. A rotation shaft 255 of the rotation mechanism 267 is connected to the boat 217 via the seal cap 219. The rotation mechanism 267 is configured to rotate the boat 217 to rotate the wafers 200. The seal cap 219 is configured to be moved up and down in the vertical direction by a boat elevator 115 as an elevating mechanism installed vertically outside the outer tube 203. The boat elevator 115 is configured to be able to load and unload the boat 217 into and from the process chamber 201 by moving the seal cap 219 up and down. The boat elevator 115 is configured as a transfer device (transfer mechanism) that transfers the boat 217 and the wafers 200 accommodated in the boat 217 into and out of the process chamber 201.

The boat 217 serving as a substrate support is configured to support a plurality of wafers 200, e.g., 1 to 200 wafers, in such a state that the wafers 200 are arranged in a horizontal posture and in multiple stages along a vertical direction with the centers of the wafers 200 aligned with one another. As such, the boat 217 is configured to arrange the wafers 200 to be spaced apart from each other. The boat 217 is made of, for example, a heat-resistant material such as quartz or SiC. Under the boat 217, heat-insulating plates 218 made of, for example, a heat-resistant material such as quartz or SiC, are supported in a horizontal posture in multiple stages (not shown). This configuration makes it difficult for the heat from the heater 207 to be transferred toward the seal cap 219. However, the present embodiments are not limited to the above-described form. For example, instead of installing the heat-insulating plates 218 under the boat 217, a heat-insulating cylinder configured as a cylindrical member made of a heat-resistant material such as quartz or SiC may be installed.

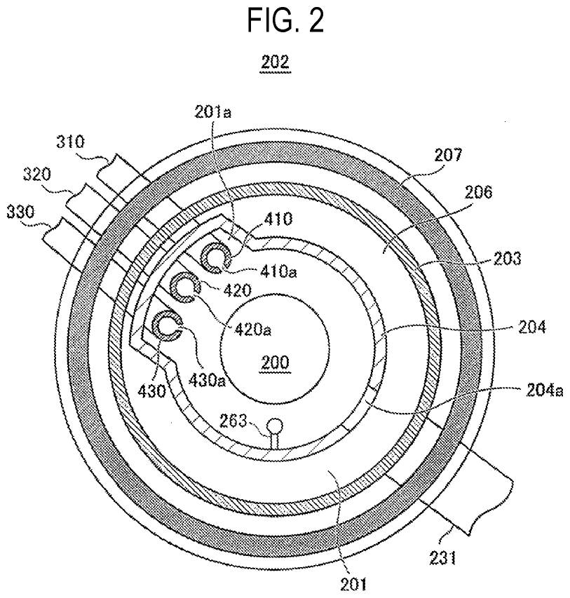

As shown in FIG. 2, a temperature sensor 263 as a temperature detector is installed in the inner tube 204. By adjusting the amount of supplying electric power to the heater 207 based on the temperature information detected by the temperature sensor 263, the inside of the process chamber 201 has a desired temperature distribution. The temperature sensor 263 is formed in an L shape just like the nozzles 410, 420, and 430, and is installed along the inner wall of the inner tube 204

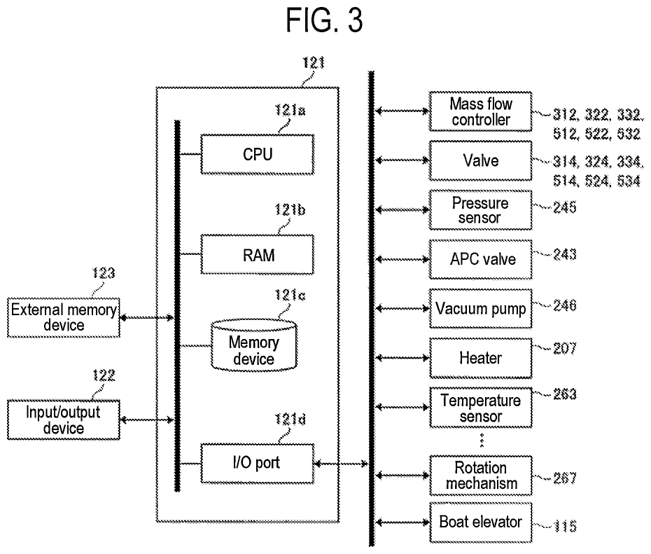

As shown in FIG. 3, a controller 121 as a control part (control means) is configured as a computer including a CPU (Central Processing Unit) 121a, a RAM (Random Access Memory) 121b, a memory device 121c, and an I/O port 121d. The RAM 121b, the memory device 121c, and the I/O port 121d are configured to exchange data with the CPU 121a via an internal bus. An input/output device 122 configured as, for example, a touch panel or the like is connected to the controller 121.

The memory device 121c is configured by, for example, a flash memory, a HDD (Hard Disk Drive), or the like. The memory device 121c readably stores a control program for controlling the operation of the substrate processing apparatus, a process recipe in which procedures and conditions of a below-described method of manufacturing a semiconductor device are written, and the like. The process recipe is a combination that can obtain a predetermined result by causing the controller 121 to execute the respective processes (respective steps) in a below-described method of manufacturing a semiconductor. The process recipe functions as a program. Hereinafter, the process recipe, the control program, and the like are collectively and simply referred to as a program. As used herein, the term “program” may refer to a case of including only the process recipe, a case of including only the control program, or a case of including a combination of the process recipe and the control program. The RAM 121b is configured as a memory area (work area) in which the program read by the CPU 121a, data, and the like are temporarily held.

The I/O port 121d is controllably connected to the MFCs 312, 322, 332, 512, 522, and 532, the valves 314, 324, 334, 514, 524, and 534, the pressure sensor 245, the APC valve 243, the vacuum pump 246, the heater 207, the temperature sensor 263, the rotation mechanism 267, the boat elevator 115, and the like. As used herein, the term “connected” includes being electrically directly connected, being indirectly connected, and being configured to be able to directly or indirectly transmit and receive electrical signals.

The CPU 121a is configured to read the control program from the memory device 121c and execute the control program thud read. The CPU 121a is also configured to read the recipe from the memory device 121c in response to an operation command inputted from the input/output device 122 or the like. The CPU 121a is configured to control, according to the contents of the recipe thus read, the operation of adjusting the flow rates of various gases by the MFCs 312, 322, 332, 512, 522, and 532, the opening/closing operation of the valves 314, 324, 334, 514, 524, and 534, the opening/closing operation of the APC valve 243, the pressure adjustment operation by the APC valve 243 based on the pressure sensor 245, the temperature adjustment operation of the heater 207 based on the temperature sensor 263, the start and stop of the vacuum pump 246, the rotation and rotation speed adjustment operation of the boat 217 by the rotation mechanism 267, the operation of raising and lowering the boat 217 by the boat elevator 115, the operation of accommodating the wafers 200 in the boat 217, and the like.

The controller 121 may be configured by installing, in a computer, the aforementioned program stored in an external memory device (e.g., a magnetic tape, a magnetic disk such as a flexible disk or hard disk, an optical disk such as a CD or a DVD, a magneto-optical disk such as a MO or the like, or a semiconductor memory such as a USB memory or a memory card) 123. The memory device 121c and the external memory device 123 are configured as a non-transitory computer-readable recording medium. Hereinafter, the memory device 121c and the external memory device 123 are collectively and simply referred to as a recording medium. As used herein, the term “recording medium” may refer to a case of including only the memory device 121c, a case of including only the external memory device 123, or a case of including both the memory device 121c and the external memory device 123. The provision of the program to the computer may be performed by using a communication means such as the Internet or a dedicated line without using the external memory device 123.

### (2) Substrate-Processing Process (Film-Forming Process)

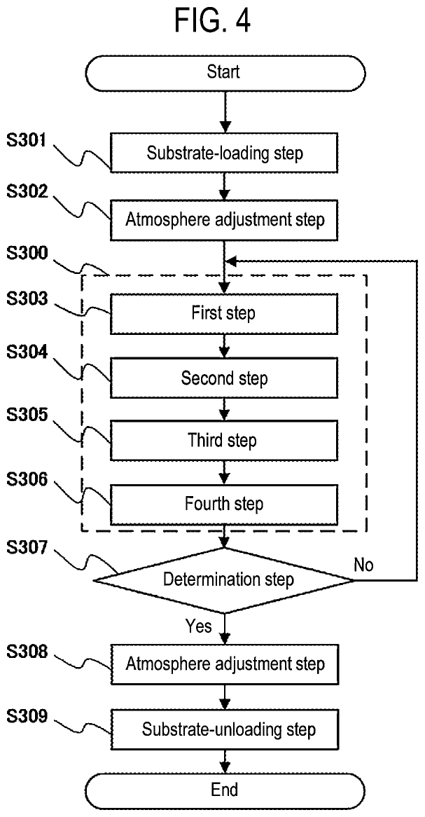

As a process of manufacturing a semiconductor device, an example of a process of forming a metal film constituting, for example, a gate electrode, on a wafer 200 will be described with reference to FIG. 4. The process of forming the metal film is performed by using the process furnace 202 of the substrate processing apparatus 10 described above. In the following description, the operation of each of the parts constituting the substrate processing apparatus 10 is controlled by the controller 121.

When the term “wafer” is used herein, it may refer to “a wafer itself” or “a laminated body of a wafer and a predetermined layer or film formed on the surface of the wafer.” When the term “a surface of a wafer” is used herein, it may refer to “a surface of a wafer itself” or “a surface of a predetermined layer or a film formed on a wafer.” In addition, when the term “substrate” is used herein, it may be synonymous with the term “wafer.”

Further, the phrase “TiN film not containing a Si atom” includes a case where the TiN film does not contain any Si atom, a case where the TiN film contains almost no Si atom, and a case where the Si content in the TiN film is extremely low, such as a case where the TiN film contains substantially no Si atom, and the like. For example, the phrase “TiN film not containing a Si atom” includes a case where the Si content in the TiN film is, for example, about 4%, preferably 4% or less.

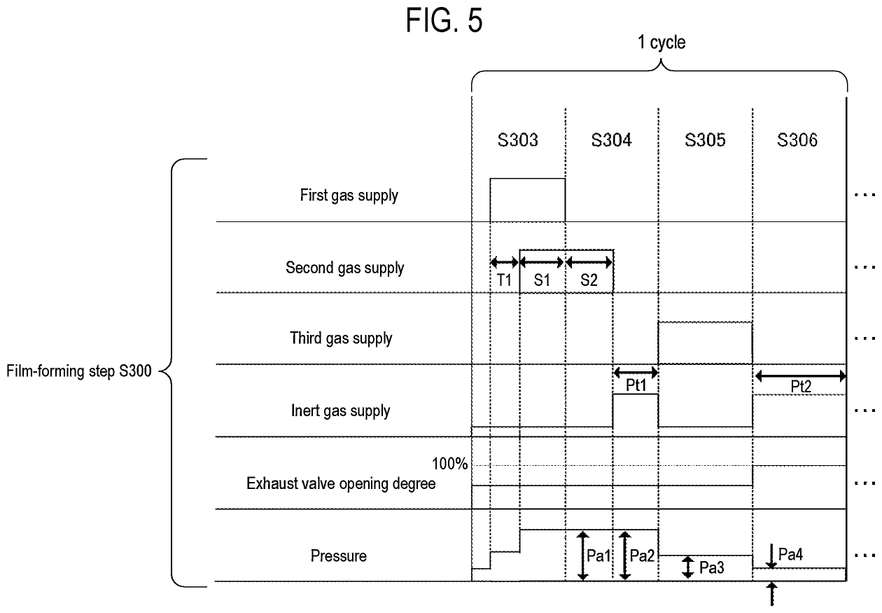

The gas supply sequence or the flow of a method of manufacturing a semiconductor device according to the present disclosure will be described below with reference to FIGS. 4 to 12. The horizontal axis in FIGS. 5 to 8 and 9 to 12 represents the time, and the vertical axis therein represents the each gas supply amount, the valve-opening degree, and the pressure. The supply amount, the valve-opening degree, and the pressure have arbitrary units.

### (Substrate-Loading Step S301)

When a plurality of wafers 200 is charged into the boat 217 (wafer charging), as shown in FIG. 1, the boat 217 supporting the plurality of wafers 200 is lifted by the boat elevator 115 and loaded into the process chamber 201 (boat loading). In this state, the seal cap 219 closes the lower end opening of the reaction tube 203 via the O-ring 220.

### (Atmosphere Adjustment Step S302)

The inside of the process chamber 201 is evacuated by the vacuum pump 246 so as to have a desired pressure (degree of vacuum). At this time, the pressure in the process chamber 201 is measured by the pressure sensor 245, and the APC valve 243 is feedback-controlled based on the measured pressure information (pressure regulation). The vacuum pump 246 keeps operating at least until the process to the wafers 200 is completed. Furthermore, the inside of the process chamber 201 is heated by the heater 207 so as to reach a desired temperature. At this time, the amount of supplying electric power to the heater 207 is feedback-controlled based on the temperature information detected by the temperature sensor 263 so that the inside of the process chamber 201 has a desired temperature distribution (temperature adjustment). The heating of the inside of the process chamber 201 by the heater 207 is continuously performed at least until the process to the wafers 200 is completed.

### [First Step S303] (TiCl₄ Gas Supply)

The valve 314 is opened to allow a TiCl₄ gas, which is a precursor gas, to flow into the gas supply pipe 310. The flow rate of the TiCl₄ gas is adjusted by the MFC 312. The TiCl₄ gas is supplied into the process chamber 201 from the gas supply holes 410a of the nozzle 410, and is exhausted from the exhaust pipe 231. At this time, the TiCl₄ gas is supplied to the wafers 200. In parallel with this, the valve 514 is opened to allow an inert gas such as a N₂ gas or the like to flow into the gas supply pipe 510. The flow rate of the N₂ gas flowing through the gas supply pipe 510 is adjusted by the MFC 512. The N₂ gas is supplied into the process chamber 201 together with the TiCl₄ gas, and is exhausted from the exhaust pipe 231. At this time, in order to prevent the TiCl₄ gas from entering the nozzles 420 and 430, the valves 524 and 534 are opened to allow the N₂ gas to flow into the gas supply pipes 520 and 530. The N₂ gas is supplied into the process chamber 201 via the gas supply pipes 320 and 330 and the nozzles 420 and 430, and is exhausted from the exhaust pipe 231.

At this time, the APC valve 243 is adjusted so that the pressure in the process chamber 201 is set to, for example, a pressure in the range of 1 to 3990 Pa. The supply flow rate of the TiCl₄ gas controlled by the MFC 312 is set to, for example, a flow rate in the range of 0.1 to 2.0 slm. The supply flow rate of the N₂ gas controlled by the MFC 512, 522, and 532 is set to, for example, a flow rate in the range of 0.1 to 20 slm. At this time, the temperature of the heater 207 is set so that the temperature of the wafers 200 is in the range of, for example, 300 to 600 degrees C.

At this time, the gases flowing into the process chamber 201 are the TiCl₄ gas and the N₂ gas. By supplying the TiCl₄ gas, a Ti-containing layer is formed on the wafer 200 (the base film on the surface). The Ti-containing layer may be a Ti layer containing Cl, an adsorption layer of TiCl₄, or both of them. The time during which only the TiCl₄ gas and the N₂ gas are supplied is a predetermined T1 time.

### (SiH₄ Gas Supply)

After a lapse of a predetermined time (T1), for example, 0.01 to 5 seconds from the start of supply of the TiCl₄ gas, the valve 324 is opened to allow a SiH₄ gas, which is a reducing gas, to flow into the gas supply pipe 320. The flow rate of the SiH₄ gas is adjusted by the MFC 322. The SiH₄ gas is supplied into the process chamber 201 from the gas supply holes 420a of the nozzle 420, and is exhausted from the exhaust pipe 231. At this time, the valve 524 is simultaneously opened to allow an inert gas such as a N₂ gas to flow into the gas supply pipe 520. The flow rate of the N₂ gas flowing through the gas supply pipe 520 is adjusted by the MFC 522. The N₂ gas is supplied into the process chamber 201 together with the SiH₄ gas, and is exhausted from the exhaust pipe 231. At this time, in order to prevent the TiCl₄ gas and the SiH₄ gas from entering the nozzle 430, the valve 534 is opened to allow the N₂ gas to flow into the gas supply pipe 530. The N₂ gas is supplied into the process chamber 201 via the gas supply pipe 330 and the nozzle 430, and is exhausted from the exhaust pipe 231. At this time, the TiCl₄ gas, the SiH₄ gas and the N₂ gas are simultaneously supplied to the wafers 200. That is, there is a period (timing) in which at least the TiCl₄ gas and the SiH₄ gas are supplied in parallel. This period is also called a first process. The period during which the first process is performed is also referred to as first timing. The time during which the TiCl₄ gas and the SiH₄ gas are simultaneously supplied is defined as S1. In this regard, preferably, time S1>time T1. With such a configuration, it is possible to suppress the adsorption of HCl on the surfaces of the wafers 200 and to enhance the effect of removing HCl in the process chamber 201.

At this time, the APC valve 243 is adjusted to set the pressure in the process chamber 201 to, for example, 130 to 3990 Pa, preferably 500 to 2660 Pa, more preferably 600 to 1500 Pa. If the pressure in the process chamber 201 is lower than 130 Pa, Si contained in the SiH₄ gas may enter the Ti-containing layer, and the Si content in the film-formed TiN film may increase, thereby forming a TiSiN film. Similarly, if the pressure in the process chamber 201 is higher than 3990 Pa, Si contained in the SiH₄ gas may enter the Ti-containing layer, and the Si content in the film-formed TiN film may increase, thereby forming a TiSiN. As described above, if the pressure in the process chamber 201 is too low or too high, the element composition of the film to be film-formed may be changed. The supply flow rate of the SiH₄ gas controlled by the MFC 322 is set to be equal to or higher than the flow rate of the TiCl₄ gas. For example, the supply flow rate of the SiH₄ gas is set to fall in the range of 0.1 to 5 slm, preferably 0.3 to 3 slm, more preferably 0.5 to 2 slm. The supply flow rate of the N₂ gas controlled by the MFC 512, 522, and 532 is set to fall in the range of, for example, 0.01 to 20 slm, preferably 0.1 to 10 slm, more preferably 0.1 to 1 slm. At this time, the temperature of the heater 207 is set to the same temperature as that of the TiCl₄ gas supply step.

After a lapse of a predetermined time, for example, 0.01 to 10 seconds, from the start of the supply of the TiCl₄ gas, the valve 314 of the gas supply pipe 310 is closed to stop the supply of the TiCl₄ gas. That is, the time for supplying the TiCl₄ gas to the wafers 200 is set to, for example, a time in the range of 0.01 to 10 seconds. After the supply of the TiCl₄ gas is stopped, the SiH₄ gas and the N₂ gas are supplied to the wafers 200 for a predetermined S2 time. The process in which the SiH₄ gas is supplied to the wafers 200 without supplying the TiCl₄ gas in this way is referred to as second process. The period during which the second process is performed is also referred to as second timing. Further, the N₂ gas is continuously supplied from the gas supply pipes 510 and 530 to the process chamber 201 via the gas supply pipes 310 and 330 and the nozzles 410 and 430. As a result, it is possible to suppress the intrusion of the SiH₄ gas from the process chamber 201 into the nozzles 410 and 430.

### [Second Step S304] (Residual Gas Removal)

After a lapse of a predetermined time, for example, 0.01 to 60 seconds, preferably 0.1 to 30 seconds, more preferably 1 to 20 seconds, from the start of the supply of the SiH₄ gas, the valve 324 is closed to stop the supply of the SiH₄ gas. That is, the time for supplying the SiH₄ gas to the wafers 200 is set to, for example, 0.01 to 60 seconds, preferably 0.1 to 30 seconds, more preferably 1 to 20 seconds. If the time for supplying the SiH₄ gas to the wafers 200 is shorter than 0.01 seconds, the growth-inhibiting factor HCl may not be sufficiently reduced by the SiH₄ gas and may remain in the Ti-containing layer. If the time for supplying the SiH₄ gas to the wafers 200 is longer than 60 seconds, the Si contained in the SiH₄ gas may enter the Ti-containing layer, and the Si content in the film-formed TiN film may increase, thereby forming a TiSiN film. Preferably, the supply time of the SiH₄ is set to be longer than the supply time of TiCl₄. Further, the supply time (S2) of the SiH₄ gas after stopping the supply of the TiCl₄ gas is set to be equal to or longer than S1. That is, there is a relationship of S2≥S1. With such a configuration, it is possible to reduce the Cl component in the Ti-containing layer and to enhance the effect of removing HCl in the process chamber 201.

Next, simultaneously with the stop of supply of the SiH₄ gas, the amount of the N₂ gas supplied as an inert gas from the nozzles 410, 420, and 430 into the process chamber 201 is increased. Further, while the APC valve 243 of the exhaust pipe 231 is left open, the atmosphere in the process chamber 201 is exhausted by the vacuum pump 246, whereby the TiCl₄ gas and the SiH₄ gas unreacted or contributed to the formation of the Ti-containing layer, which remain in the process chamber 201, are removed from the process chamber 201. At this time, the valves 514, 524, and 534 are left open to maintain the supply of the N₂ gas into the process chamber 201. The N₂ gas acts as a purge gas, and can enhance the effect of removing the TiCl₄ gas and the SiH₄ gas unreacted or contributed to the formation of the Ti-containing layer, which remain in the process chamber 201, from the process chamber 201. At this time, HCl, which is a growth-inhibiting factor, reacts with SiH₄ and is discharged from the process chamber 201 as silicon tetrachloride (SiCl₄) and H₂. In addition, the SiH₄ gas remaining in the process chamber 201 is diluted with the N₂ gas and exhausted to the exhaust pipe 231.

The N₂ gas flow rate at this time is controlled by each of the MFCs 512, 522, and 532 so that the total flow rate of the N₂ gas supplied from the nozzles 410, 420, and 430 becomes 10 to 60 slm, preferably 60 slm. The valve-opening degree of the APC valve is set to 0% to 70%. One or both of the valve-opening degree of the APC valve 243 and the flow rate in each of the MFCs 512, 522, and 532 may be controlled so that the pressure Pa2 in the process chamber 201 at this time becomes equivalent to the pressure Pa1 at the time of supplying the SiH₄ gas. The pressure Pa2 is, for example, 1 Torr to 20 Torr, and preferably, is set to 10 Torr. The process of maintaining the pressure Pa2 in the process chamber 201 substantially equal to the pressure Pa1 at the time of supplying the SiH₄ gas in this way is called a third process. In addition, the period during which the third process is performed is also referred to as third timing.

### (Pressures Pa1 and Pa2)

The pressure ratio between the pressure Pa1 and the pressure Pa2 is affected by the dimensions of the respective parts of the substrate processing apparatus 10, the number of wafers 200, the surface area of the wafers 200, and the like. The dimensions of the respective parts of the substrate processing apparatus 10 include, for example, the volume of the process chamber 201, the lengths of the nozzles 410, 420, and 430, the lengths of the gas supply pipes 310, 320, and 330, the volume of the exhaust pipe 231, the position and diameter of the APC valve 243, and the like. The pressure ratio relationship between Pa1 and Pa2 may be, for example, Pa1=Pa2×±50%. Preferably, the valve-opening degrees of the APC valve 243 and the MFCs 512, 522, and 532 are controlled so that Pa1=Pa2×±10%. The pressure Pa2 can be controlled by either or both of the flow rate of each of the MFCs 512, 522, and 532 and the valve-opening degree of the APC valve 243. A sequence example of a case of increasing and decreasing the pressure Pa2 will be described below.

### (Pa2>Pa1)

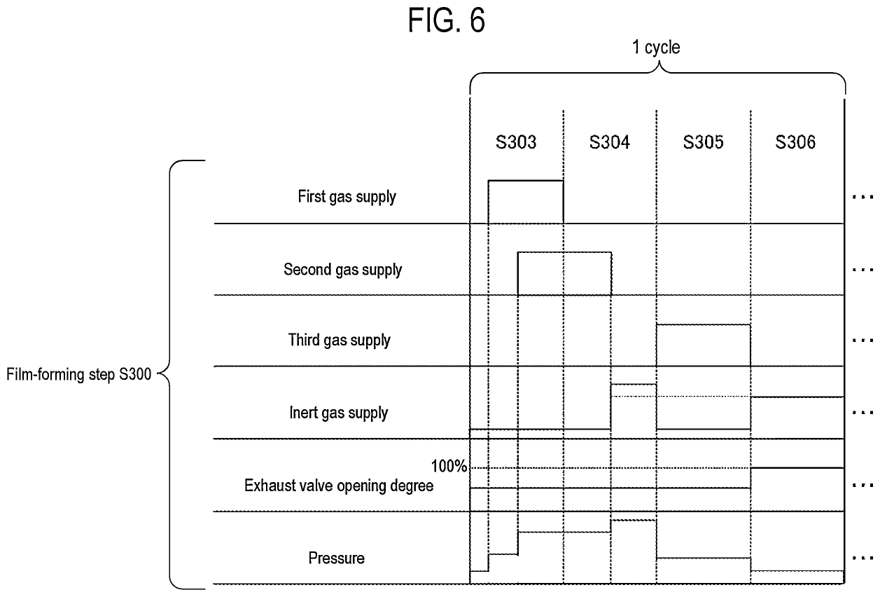

FIG. 6 shows a gas supply sequence in which the pressure Pa2 is increased to be higher than the pressure Pa1. As shown in FIG. 6, when increasing the pressure Pa2, it is preferable to increase the flow rate of the N₂ gas as an inert gas. With this configuration, the Si-containing gas molecules and by-product molecules existing in the process chamber 201 can be swept away by the inert gas molecules. This makes it possible to enhance the discharge efficiency.

### (Pa2<Pa1)

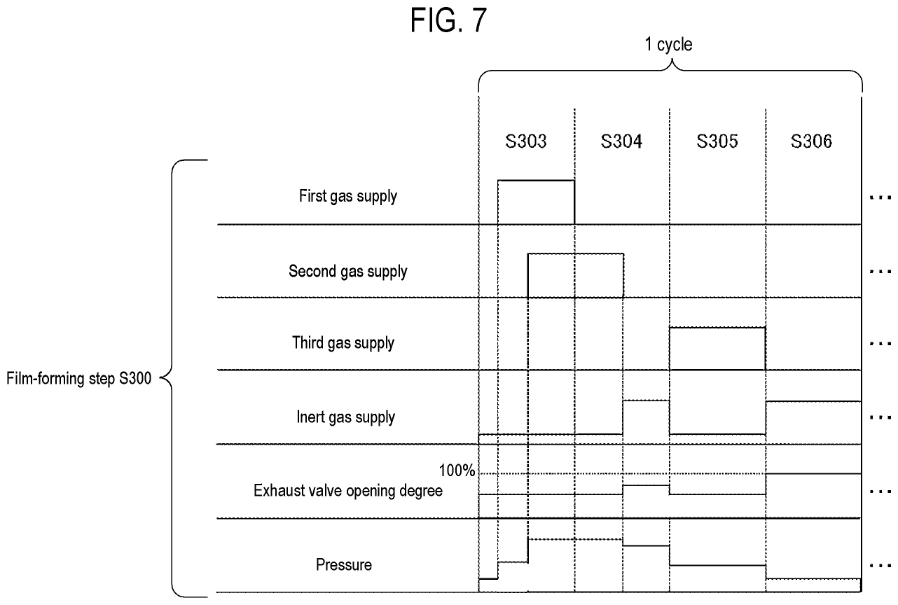

FIG. 7 shows a gas supply sequence in which the pressure Pa2 is reduced to be lower than the pressure Pa1. As shown in FIG. 7, when reducing the pressure Pa2, it is preferable to increase the valve-opening degree of the APC valve 243. With such a configuration, the exhaust speed can be increased, and the discharge efficiency of Si-containing gas molecules and by-product molecules existing in the process chamber 201 can be enhanced.

### (Inert Gas Flow Rate)

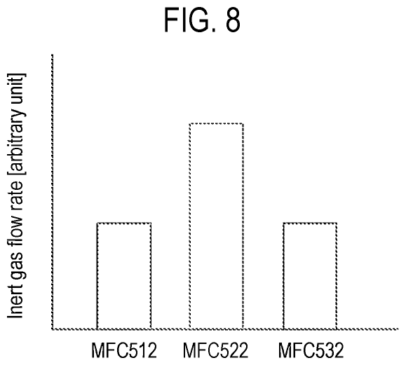

The flow rate of the N₂ gas the inert gas supplied to each of the nozzles 410, 420, and 430 is controlled by each of the MFCs 512, 522, and 532. The flow rate of the N₂ gas supplied to each of the nozzles 410, 420, and 430 may be controlled so as to be uniform. Preferably, as shown in FIG. 8, the flow rate of the N₂ gas supplied to the nozzle 420, which has supplied the SiH₄ gas, is set to be larger than the flow rate of the N₂ gas supplied to the other nozzles 410 and 430. With such a configuration, it is possible to enhance the discharge efficiency of the SiH₄ gas existing in the nozzle 420.

### (Process of Increasing Flow Rate of Inert Gas)

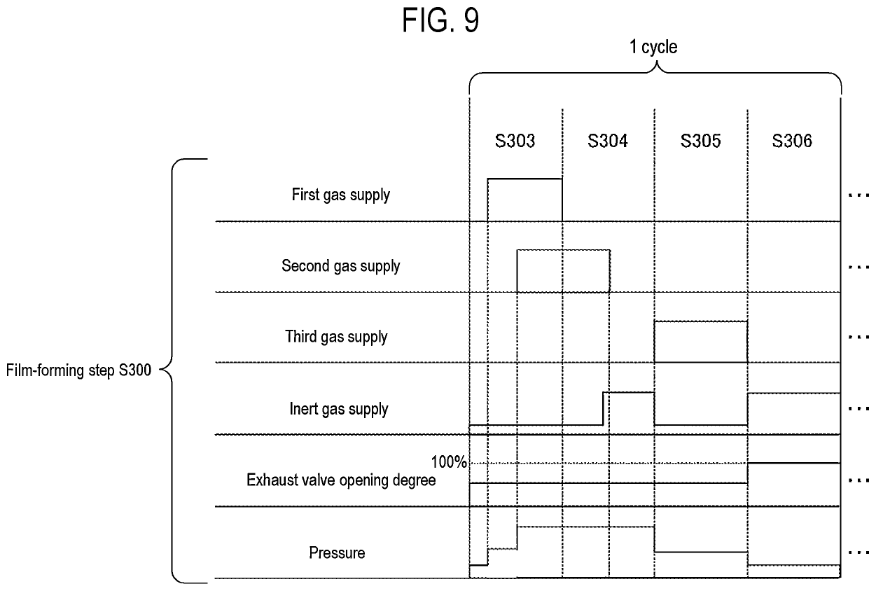

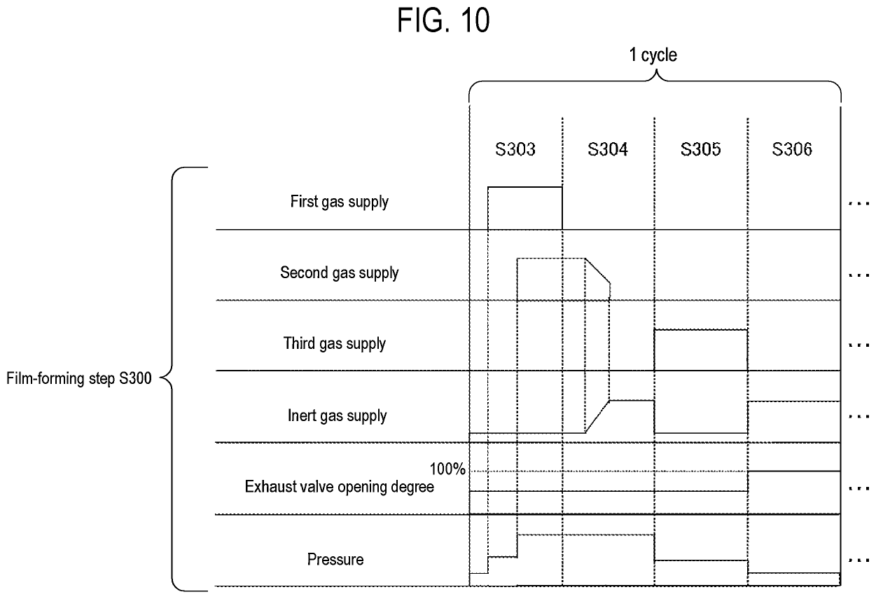

Next, the process of increasing the flow rate of the N₂ gas as the inert gas will be described. In FIGS. 5 to 7, there is shown the process of increasing the flow rate of the N₂ gas simultaneously with the stop of supply of the SiH₄ gas. However, the present disclosure is not limited thereto. The gas supply sequences shown in FIGS. 9 and 10 may be used. For example, as shown in FIG. 9, the supply amount of the N₂ gas is started to increase before stopping the supply of the SiH₄ gas. Further, as shown in FIG. 10, immediately before stopping the SiH₄ gas, the supply amount of the N₂ gas may be increased while reducing the supply amount of the SiH₄ gas. By using such a gas supply sequence, even if the distance from each of the MFCs 512, 522, and 532 to the process chamber 201 is long and even if there is a time lag until the gas subjected to the flow rate change reaches the process chamber 201, it is possible to change the pressure in the process chamber 201 to a predetermined pressure. That is, it is possible to suppress the fluctuation of the pressure during the increase in the flow rates of the SiH₄ gas and the N₂ gas.

### (Inert Gas Supply Time Pt1)

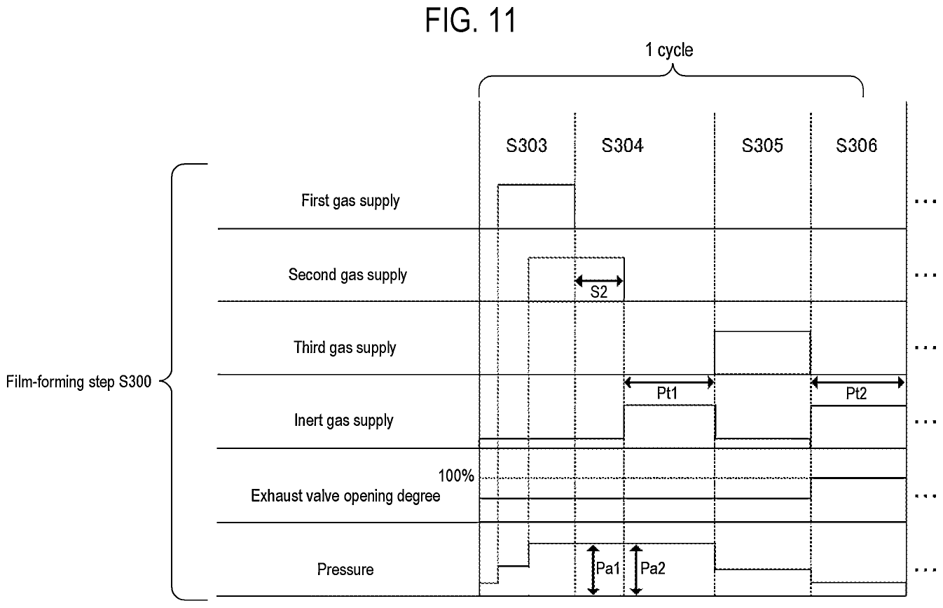

Next, the inert gas supply time Pt1 will be described with reference to FIGS. 5 and 11. The time Pt1 for supplying the inert gas and maintaining the pressure Pa2 is set to be at least equal to or longer than the supply time S2 only for SiH₄ after the supply of TiCl₄ is stopped. As shown in FIG. 11, Pt1 may be set to be longer than S2. With such a configuration, it is possible to reduce the concentration of the SiH₄ gas and the by-products in the process chamber 201. In addition, the time Pt1 may be set to be equal to the time Pt2 in the subsequent purging step S306. The relationship of Pt1≤Pt2 is established. Although the time Pt1 may be set to be longer than the time Pt2, the total time of the film-forming process S300 becomes long, which may affect the manufacturing throughput of a semiconductor-manufacturing apparatus. Therefore, the time Pt1 is set to satisfy the above relationship.

### (Vacuum Evacuation Step)

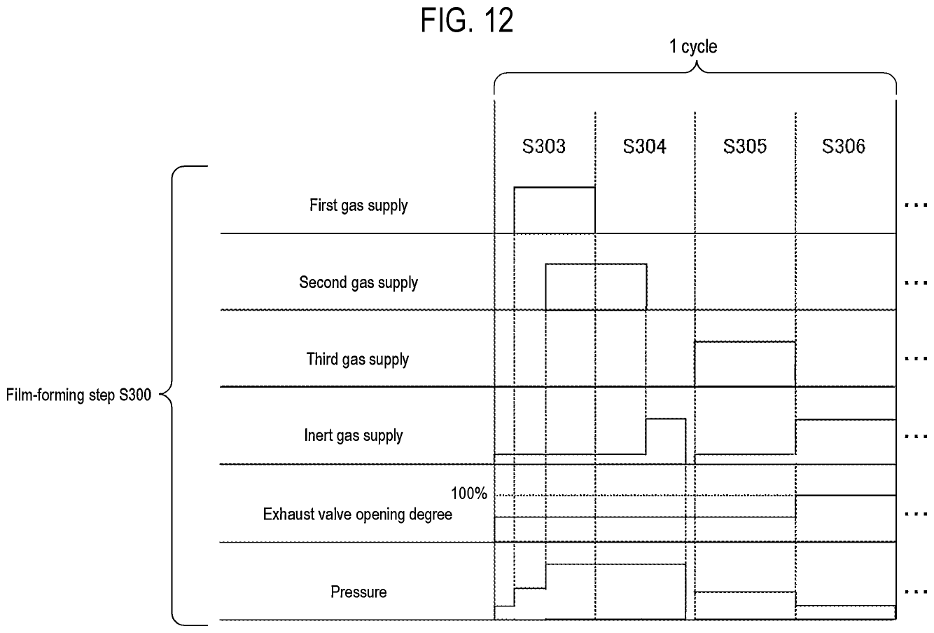

As shown in FIG. 12, there may be provided a vacuum evacuation step in which the flow rate of the N₂ gas as the inert gas is increased to keep the pressure Pa2 equal to the pressure Pa1 for a predetermined time and then the flow rate of the inert gas is decreased to reduce the pressure in the process chamber 201. By providing this step, the amount of the SiH₄ gas and the amount of the by-products can be reduced at the start of the next step S305, and ammonium chloride (NH₄Cl) as a by-product produced in the next step S305 can be reduced. Although FIG. 12 shows an example in which the inert gas is stopped, the flow rate of the inert gas may be set to be equal to that of the step S303 or the next step S305. With this configuration, it is possible to suppress the fluctuation in pressure in the next step S305.

### [Third Step S305] (NH₃ Gas Supply)

After removing the residual gas in the process chamber 201, the valve 334 is opened to allow a NH₃ gas as a reaction gas to flow into the gas supply pipe 330. The flow rate of the NH₃ gas is adjusted by the MFC 332. The NH₃ gas is supplied into the process chamber 201 from the gas supply holes 430a of the nozzle 430, and is exhausted from the exhaust pipe 231. At this time, the NH₃ gas is supplied to the wafers 200. At the same time, the valve 534 is opened to allow a N₂ gas to flow into the gas supply pipe 530. The flow rate of the N₂ gas flowing through the gas supply pipe 530 is adjusted by the MFC 532. The N₂ gas is supplied into the process chamber 201 together with the NH₃ gas, and is exhausted from the exhaust pipe 231. At this time, in order to prevent the intrusion of the NH₃ gas into the nozzles 410 and 420, the valves 514 and 524 are opened to allow the N₂ gas to flow into the gas supply pipes 510 and 520. The N₂ gas is supplied into the process chamber 201 via the gas supply pipes 310 and 320 and the nozzles 410 and 420, and is exhausted from the exhaust pipe 231.

At this time, the APC valve 243 is adjusted so that the pressure in the process chamber 201 is set to, for example, a pressure in the range of 1 to 3990 Pa. The supply flow rate of the NH₃ gas controlled by the MFC 332 is set to, for example, a flow rate in the range of 0.1 to 30 slm. The supply flow rate of the N₂ gas controlled by the MFCs 512, 522, and 532 is set to, for example, a flow rate in the range of 0.1 to 30 slm. The time for supplying the NH₃ gas to the wafers 200 is set to, for example, a time in the range of 0.01 to 30 seconds. The temperature of the heater 207 at this time is set to the same temperature as that of the TiCl₄ gas supply step.

At this time, the gases flowing in the process chamber 201 are the NH₃ gas and the N₂ gas. The NH₃ gas undergoes a replacement reaction with at least a part of the Ti-containing layer formed on each of the wafers 200 in the first step S303. During the replacement reaction, Ti contained in the Ti-containing layer and N contained in the NH₃ gas are bonded to form a TiN layer containing Ti and N and substantially free of Si on each of the wafers 200.

### [Fourth Step S306] (Residual Gas Removal)

After forming the TiN layer, the valve 334 is closed to stop the supply of the NH₃ gas. Then, by the same process procedure as in the second step described above, the NH₃ gas unreacted or contributed to the formation of the TiN layer and the reaction by-products, which remain in the process chamber 201, are removed from the process chamber 201. At this time, the valve-opening degree of the APC valve 243 is set to an approximately fully opened state (approximately 100%), and the total flow rate of the N₂ gas is set to 1 slm to 100 slm. Specifically, each of the MFCs and the APC valve 243 are controlled to set the pressure to 180 Pa at 60 slm. In this case, the pressure Pa4 is a pressure sufficiently lower than the aforementioned pressure Pa2 and the pressure Pa3 in the third step S305, and has a relationship of Pa4<Pa2 and Pa4<Pa3. With such a configuration, the by-products produced in one cycle can be exhausted, and the influence on the next cycle can be reduced.

### (Determination Step S307)

It is determined whether or not the cycle of sequentially performing the first step S303 to the fourth step S306 described above has been performed until a film having a predetermined thickness is formed. If the cycle has not been performed a predetermined number of times, the first step S303 to the fourth step S306 are repeatedly performed. If the cycle has been performed a predetermined number of times, the next atmosphere adjustment step S308 is performed. In this regard, the predetermined number of times is n times, and n is 1 or more. By performing the cycle a predetermined number of times, a film having a predetermined thickness is formed on each of the wafers 200. The aforementioned cycle is preferably repeated a plurality of times. In the present embodiments, for example, a TiN film having a thickness of 0.5 to 5.0 nm is formed.

### (Atmosphere Adjustment Step S308)

A N₂ gas is supplied into the process chamber 201 from each of the gas supply pipes 510, 520, and 530, and is exhausted from the exhaust pipe 231. The N₂ gas acts as a purge gas, whereby the inside of the process chamber 201 is purged with the inert gas, and the gas and by-products remaining in the process chamber 201 are removed from the inside of the process chamber 201 (after-purging). Thereafter, the atmosphere in the process chamber 201 is replaced with the inert gas (inert gas replacement), and the pressure in the process chamber 201 is restored to the atmospheric pressure (atmospheric pressure restoration).

### (Substrate-Unloading Step S309)

Thereafter, the seal cap 219 is lowered by the boat elevator 115 to open the lower end of the reaction tube 203. Then, the processed wafers 200 are unloaded from the lower end of the reaction tube 203 to the outside of the reaction tube 203 while being supported by the boat 217 (boat unloading). Thereafter, the processed wafers 200 are taken out from the boat 217 (wafer discharging).

### (3) Effects of the Embodiments

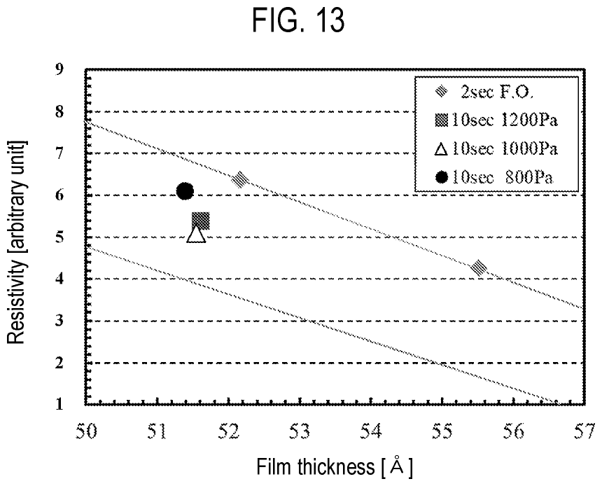

According to the present embodiments, one or more of the following effects may be obtained. (a) HCl generated during film formation and acting to reduce the deposition rate can be efficiently discharged, and the deposition rate can be increased. (b) The concentration of Si in the film can be reduced. (c) The resistivity can be lowered. An example of the experimental results is shown in FIG. 13. FIG. 13 shows the results obtained by changing the valve-opening degree of the exhaust valve when the flow rate of the inert gas in the second step S304 is increased and by changing the time when the flow rate of the inert gas is increased. The term “F. O.” in FIG. 13 means that the exhaust valve is fully opened, and “800 Pa,” “1000 Pa,” and “1200 Pa” are the results obtained in a state in which the exhaust valve is not fully opened. As shown in FIG. 13, the resistivity of the film can be reduced by increasing the pressure and time when the flow rate of the inert gas in the second step S304 is increased. (d) The oxidation resistance can be improved. (e) SiH₄ in the process chamber can be diluted with the inert gas and discharged from the process chamber to the exhaust part, thereby preventing the gas having a high concentration of SiH₄ from being instantaneously discharged to the exhaust part. As a result, an unexpected reaction of SiH₄ in the subsequent stage of the vacuum pump can be suppressed.

Further, in the above-described embodiments, TiCl₄ is used as the precursor gas. However, the present disclosure is not limited thereto. The present disclosure may be applied to a halogen-containing gas such as tungsten hexafluoride (WF₆), tantalum tetrachloride (TaCl₄), tungsten hexachloride (WCl₆), tungsten pentachloride (WCl₅), molybdenum tetrachloride (MoCl₄), silicon tetrachloride (SiCl₄), disilicon hexachloride (Si₂Cl₆), hexachlorodisilane (HCDS) or the like, preferably a Cl-containing gas, and film types formed by using them. Furthermore, the present disclosure may be applied to a Si-based gas such as trichlorodisilane (TCS) or the like, in addition to the tantalum (Ta)-based gas, and film types formed by using film them.

In the above-described embodiments, SiH₄ is used as the reducing gas for reducing HCl. However, the present disclosure is not limited thereto. A H-containing gas, for example, disilane (Si₂H₆), trisdimethylaminosilane (SiH[N(CH₃)₂]₃), diborane (B₂H₆), phosphine (PH₃), an active-hydrogen-containing gas, a hydrogen-containing gas, or the like may be used.

Further, in the above-described embodiments, one type of reducing gas is used. However, the present disclosure is not limited thereto. Two or more types of reducing gases may be used.

Further, in the above-described embodiments, HCl is used as the by-product which is reduced by using the reducing gas. However, the present disclosure is not limited thereto. The present disclosure may be applied to a case where hydrogen fluoride (HF), hydrogen iodide (HI), hydrogen bromide (HBr), or the like is generated.

Further, in the above-described embodiments, there has been described the configuration in which the TiCl₄ gas as the precursor gas and the SiH₄ gas as the reducing gas are supplied into the process chamber 201 from the nozzles 410 and 420, respectively. However, the present disclosure is not limited thereto. The TiCl₄ gas and the SiH₄ gas may be pre-mixed and supplied from one nozzle.

Further, in the above-described embodiments, there has been described the configuration in which the reducing gas is supplied simultaneously with or after the supply of the TiCl₄ gas, or simultaneously with or after the supply of the NH₃ gas. However, the present disclosure is not limited thereto. The present disclosure may be applied to a configuration in which the reducing gas is supplied at the time of supply of each of the TiCl₄ gas and the NH₃ gas, or after supply of each of the TiCl₄ gas and the NH₃ gas.

Further, in the above-described embodiments, there has been described the configuration in which film formation is performed by using the batch type substrate processing apparatus that processes a plurality of substrates at one time. However, the present disclosure is not limited thereto. The present disclosure may be suitably applied to a case where film formation is performed by using a single-substrate type substrate processing apparatus that processes one or several substrates at a time.

Further, in the above-described embodiments, there has been described the example in which the wafers are used as semiconductor substrates. However, the present disclosure may be applied to a case where a substrate-processing process is performed by using a substrate made of another material, for example, a substrate such as a ceramic substrate or a glass substrate.

According to the present disclosure, it is possible to form a low resistance film.

Although various typical embodiments and examples of the present disclosure have been described above, the present disclosure is not limited to those embodiments and examples. The embodiments and examples may be used in combination as appropriate.

What is claimed is:

1. A method of manufacturing a semiconductor device comprising steps described in the specification.
